(19) United States
(12) Patent Application Publication
(10) Pub. No.: US 2015/0307349 A1
(43) Pub. Date: Oct. 29, 2015

(54) MEMS FABRICATION TOOL AND METHOD FOR USING

(71) Applicant: Knowles Electronics, LLC, Itasca, IL (US)

(72) Inventors: Nithya Jayapratha, Naperville, IL (US); Peter V. Loeppert, Durand, IL (US); Jay Cech, St. Charles, IL (US)

(21) Appl. No.: 14/689,565

(22) Filed: Apr. 17, 2015

Related U.S. Application Data
(60) Provisional application No. 61/983,171, filed on Apr. 23, 2014.

(51) Int. Cl. B81C 99/00

(52) U.S. Cl. CPC B81C 99/002

(57) ABSTRACT

A tool includes a collet, a vacuum path, and a top die. The collet has a first end and a second end. The second end is configured so as to be coupled to an air suction device. The vacuum path is formed inside and along a length of the collet and extends from the first end to the second end of the collet. The top die is coupled to the first end of the collet. The top die includes a plurality of raised islands, and each of the plurality of raised islands including a hole. The hole communicates with the vacuum path such that a suction applied by the suction device draws air through the hole and then through the vacuum path and is sufficient to pick up a MEMS component disposed in proximity to the hole.

### CROSS REFERENCES TO RELATED APPLICATION

This patent claims benefit under 35 U.S.C. §119 (e) to U.S. Provisional Application No. 61/983,171 entitled “MEMS Fabrication Tool and Method for using” filed Apr. 23, 2015, the content of which is incorporated herein by reference in its entirety.

### TECHNICAL FIELD

This application relates to microelectromechanical system (MEMS) tools and approaches for using these tools.

### BACKGROUND OF THE INVENTION

Various types of microphones and receivers (transducers) have also been used through the years. In these devices, different electrical components are housed together within a housing or assembly. Placing the components into the assembly requires a pick and place operation. Increasing miniaturization of MEMS devices make existing pick and place tools limited in their ability to pick up and assemble the small components.

Different types of tools are used to fabricate and manufacture these devices. In one example, an assembly approach a tool picks and places MEMS or other micro components. The tool is typically a long and thin tool that uses vacuum suction to pick up a component and then the operator can move the tool (and the MEMS component) to where desired.

However, previous approaches have reached manufacturability limits. For instance, previous tools are manufactured using Electrical discharge machining (EDM) process which has a tolerance of approximately +/−25 μm. With the demand to have smaller MEMS components, the pick-and-place ability of these smaller MEMS is limited. In some instances, previous approaches have proven practically useless to pick up and move parts, especially parts having smaller dimensions. The above-mentioned problems have led to user dissatisfaction with these previous approaches

### BRIEF DESCRIPTION OF THE DRAWINGS

For a more complete understanding of the disclosure, reference should be made to the following detailed description and accompanying drawings wherein:

FIG. 1 comprises a diagram of a tool according to various embodiments of the present invention;

FIG. 2 comprises a perspective drawing of FIG. 1 according to various embodiments of the present invention;

FIG. 3 comprises a perspective diagram of the tool of FIG. 1 and FIG. 2 according to various embodiments of the present invention;

FIG. 4 comprises a drawing of the top of the die of FIGS. 1, 2, and 3 according to various embodiments of the present invention;

FIG. 5 comprises a drawing of another top of a die according to various embodiments of the present invention;

FIG. 6 comprises a cross sectional view of a die according to various embodiments of the present invention;

FIG. 7 comprises a top view of a die according to various embodiments of the present invention;

FIG. 8 comprises a cross-section diagram of a wafer used to create the die of FIG. 7 showing one aspect of a manufacturing process according to various embodiments of the present invention;

FIG. 9 comprises a cross-section diagram of a wafer used to create the die of FIG. 7 (including the back side etching) in one aspect of a manufacturing process according to various embodiments of the present invention;

FIG. 10 comprises a cross-section diagram of a wafer used to create the die of FIG. 7 (including the front side etching to create the island portions) in one aspect of a manufacturing process according to various embodiments of the present invention;

FIG. 11 comprises a cross-section diagram of a wafer used to create the die of FIG. 7 (including the front side etching to create the vacuum holes) in one aspect of a manufacturing process according to various embodiments of the present invention;

FIG. 12 comprises a cross-section diagram of a wafer used to create the die of FIG. 7 (included the coating) in one aspect of a manufacturing process according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Approaches are described herein that provide MEMS pick-and-place tools that can pick up very small components or other objects having very small dimensions. Approaches for manufacturing these tools are also described. Micro-machining problems related to smaller features on previous pick-and-place tools are overcome by utilizing the present approaches. Microelectromechanical system (MEMS) components can also be used to pick up small MEMS components without damage in a mass production environment.

Using micro fabrication techniques and including very hard materials in the tools (e.g., SiC, which is readily available in wafer form or any other hard material available in wafer form) large numbers (e.g., thousands) of small dies can be manufactured at the same time, and these small dies will act as the head of pick-and-place tools. The bottom part of the tool does not need, utilize, or require micron level features and can be machined easily using conventional EDM techniques. The top die (e.g., MEMS fabricated) is, in one aspect, bonded to the bottom stainless steel collet (e.g., EDM machined) with a pre-formed, re-workable epoxy adhesive in one example. Because the SiC top die is mass produced, and the bottom stainless steel collet can be re-used, the present approaches achieve a significant cost advantage compared to previous approaches. By “collet” and used herein, it is meant any holding device (such as a chuck or chuck-like device) that is used to hold or otherwise secure the die.

In many of these embodiments, a tool includes a collet having a first end and a second end, and the second end is configured so as to be coupled to an air suction device. The tool includes a vacuum path formed inside and along a length of the collet, and the vacuum path extends from the first end to the second end of the collet. The tool includes a top die coupled to the first end of the collet. The top die includes a plurality of raised islands. Each of the plurality of raised islands includes a hole, and the hole communicates with the vacuum path. A suction applied by the suction device draws air through the hole and then through the vacuum path and is sufficient to pick up a MEMS component disposed in proximity to the hole.

In some aspects, the hole is a polygon-shaped hole. In other aspects, the hole is a circular-shaped hole.

In some examples, the vacuum path is tubular-shaped. In other examples, the first end of the collet forms a cavity and the top die is disposed in the cavity.

In some aspects, the collet is constructed of stainless steel. In some other aspects, the top die is made from titanium.

In other examples, the top die is made from a hard material which is available in wafer form. In some examples, the hard material comprises a ceramic material.

In some aspects, the top die is made from silicon carbide. In other examples, the top die is fabricated with lithography, etching, or other processes common to MEMS and semiconductor technology.

In some examples, the top die includes a coating disposed there on. In some aspects, the coating is configured and constructed of a material so as to increase a hardness of die. In some examples, the coating comprises a diamond or diamond like carbon coating.

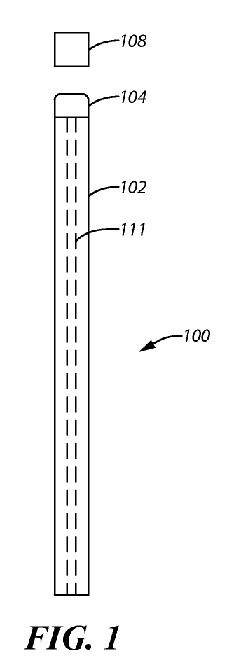

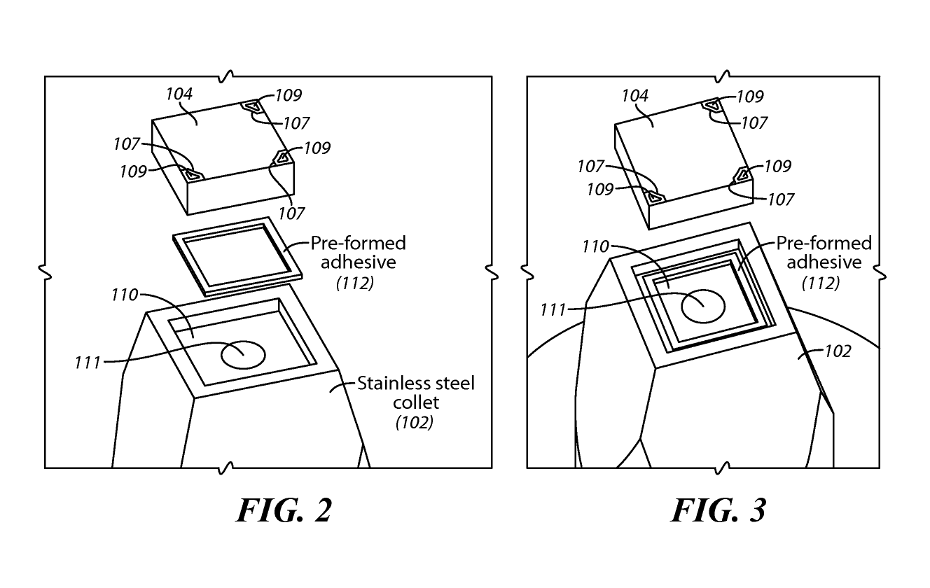

Referring now to FIGS. 1, 2, 3, and 4 one example of a tool 100 is shown. The tool includes a bottom stainless steel collet 102 and a top die 104. A vacuum path 111 is formed inside the bottom stainless steel collet 102. The tool 100 may be applied to pick up and place a MEMS component 108 (or another small-dimensioned device, component, or object).

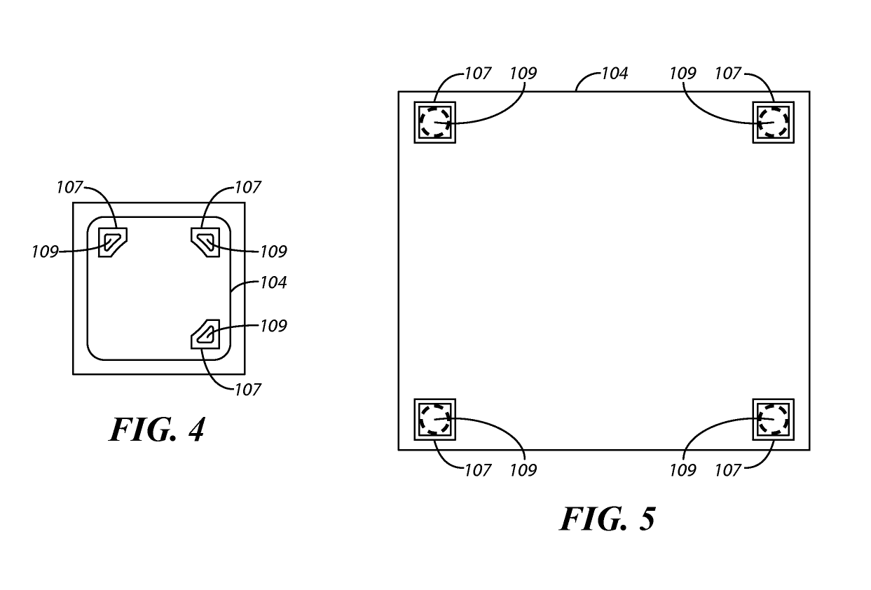

The die 104 in one example is a silicon carbon (SiC) die. As shown in FIG. 4 and FIG. 5, the approaches provided herein include bigger holes giving more vacuum area. Holes 109 extend through the die and are disposed on raised islands 107. The die sits in a cavity 110. Adhesive 112 attaches it to the collet 102. With the MEMS fabrication utilized herein, the vacuum holes 109 can be of any shape and this acts to maximize the vacuum area. A vacuum path 111 extends through the collet 102 and may be a tube-shaped opening in one example. The vacuum path 111 couples to any apparatus that can draw air (produce a suction) through the holes 109 to thereby pick up a device.

A polygon shaped vacuum hole can be used instead of conventional circular holes and, in one example, this provides better performance than the one with circular vacuum holes. In one example, using the micro fabrication techniques described herein, any shaped vacuum holes can be made to maximize the vacuum area. In one example, the vacuum area was increased by approximately 38% using a triangular hole instead of a circular hole.

Using micro fabrication techniques and very hard materials such as SiC (which is readily available in wafer form or any other hard material available in wafer form) large numbers (e.g., thousands) of small dies can be manufactured simultaneously or nearly simultaneously, and these small dies are configured as the head of the pick and place tool. As discussed, using SiC MEMS die and polygon-shaped holes, more vacuum area is provided.

Referring now to FIG. 5, another top of a die is shown. In this example, four holes or openings 109 extend through the die 104 and the holes or openings 109 are circular in shape.

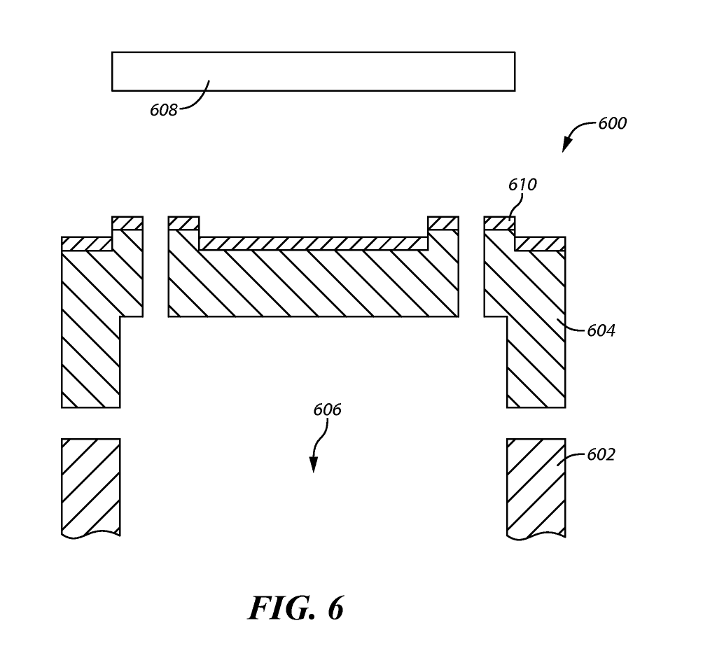

Referring now to FIG. 6, one example of a tool 600 is described. The tool 600 includes a bottom stainless steel collet 602 and a top die 604. A vacuum path 606 is formed inside the bottom stainless steel collet 602. The tool 600 may be applied to pick up and place a MEMS component 608. A coating 610 is applied to the die 604. In one aspect, the coating 610 is similar to diamond coating to increase the hardness. The coating also increases the life of the tool and can be done at the wafer level.

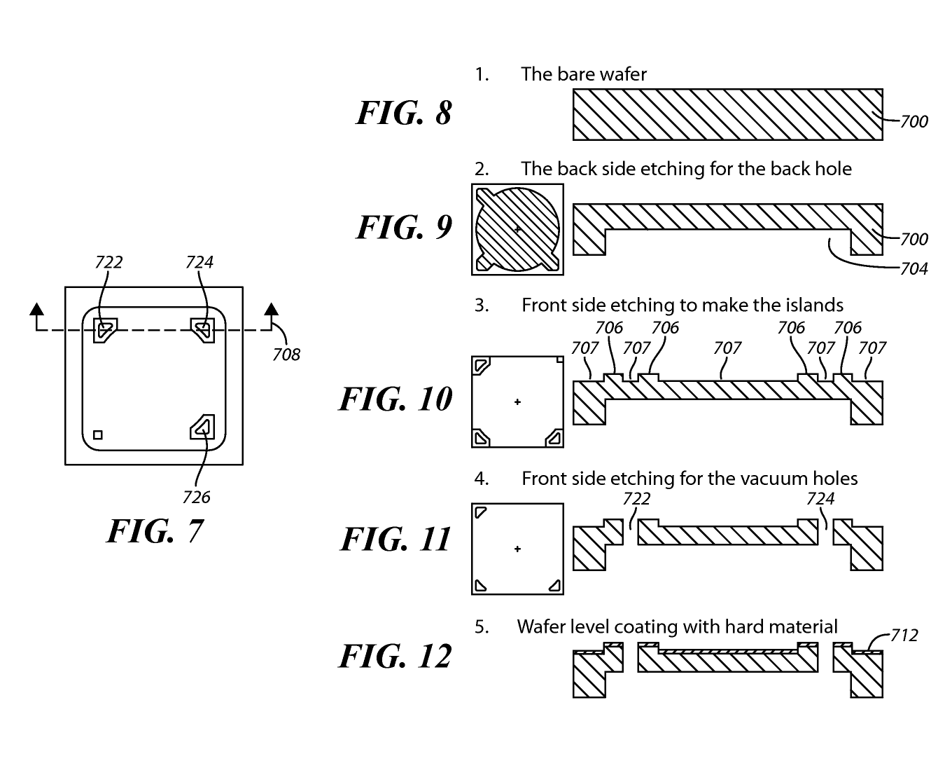

Referring now to FIGS. 7-12, one example of a process for creating the die used at the top of the tool is described. FIG. 7 shows a top view of the die 700 with holes 722, 724, and 726. Line 708 is the section line from which the views shown in FIGS. 8-12 are produced.

FIG. 8 shows a bare wafer 700. The wafer may be used to construct a top die that is placed at the top of a pick-and-place tool. FIG. 9 shows the result of an etching that creates a hole or opening 704 in the wafer 700. A masking material may be deposited on selected areas of the wafer. An etchant is applied. The areas not covered by a masking material are not protected and are removed by the etchant according to a conventional etching process.

FIG. 10 shows the top side etching process where raised portions 706 and indents 707 are created. The raised portions can be configured in a variety of different shapes and are in this example generally triangular. In one example, an etchant is applied. The areas not covered by an etching material are not protected and are removed by the etchant according to a conventional etching process.

FIG. 11 shows the etching to make the vacuum holes 722 and 724 through the raised portions 706. An etchant is applied. The areas not covered by a masking material are not protected and are removed by the etchant according to a conventional etching process.

FIG. 12 shows a coating 712 that is applied to the wafer. The coating may be a diamond coating that is used for hardness in one aspect.

When the above-mentioned die is constructed, it is disposed, in one example, on top end of a pick-and-place tool. The die can be manufactured in great numbers according to these approaches.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. A tool, the tool comprising:
a collet having a first end and a second end, the second end being configured so as to be coupled to an air suction device;
a vacuum path formed inside and along a length of the collet, the vacuum path extending from the first end to the second end of the collet;
a top die coupled to the first end of the collet;
wherein the top die includes a plurality of raised islands, each of the plurality of raised islands including a hole, the hole communicating with the vacuum path, such that a suction applied by the suction device draws air through the hole and then through the vacuum path and is sufficient to pick up a MEMS component disposed in proximity to the hole.

2. The tool of claim 1, wherein the hole is a polygon-shaped hole.

3. The tool of claim 1, wherein the hole is a circular-shaped hole.

4. The tool of claim 1, wherein vacuum path is tubular-shaped.

5. The tool of claim 1, wherein the first end of the collet forms a cavity and the top die is disposed in the cavity.

6. The tool of claim 1, wherein the collet is constructed of stainless steel.

7. The tool of claim 1, wherein the top die is made from titanium.

8. The tool of claim 1, wherein the top die is made from a hard material which is available in wafer form.

9. The tool of claim 8, wherein the hard material comprises a ceramic material.

10. The tool of claim 1, wherein the top die is made from silicon carbide.

11. The tool of claim 1, where the top die is fabricated with lithography or etching processes.

12. The tool of claim 1, wherein the top die includes a coating disposed there on.

13. The tool of claim 12, wherein the coating is configured and constructed of a material so as to increase a hardness of die.

14. The tool of claim 7, wherein the coating comprises a diamond or diamond like carbon coating.
